(19) United States
(12) Patent Application Publication
(10) Pub. No.: US 2015/0292084 A1
(43) Pub. Date: Oct. 15, 2015

(54) INTEGRATED MULTI-HEADED ATOMIZER AND VAPORIZATION SYSTEM AND METHOD

(71) Applicant: BROOKS INSTRUMENT, LLC, Harfield, PA (US)

(72) Inventors: Stephen P. Glaudel, Lebanon, NJ (US); Edward T. Fisher, Norristown, PA (US)

(21) Appl. No.: 14/352,396

(22) PCT Filed: Oct. 2, 2012
(86) PCT No.: PCT/US12/58473

§ 371 Date: Apr. 17, 2014

Related U.S. Application Data
(60) Provisional application No. 61/547,811, filed on Oct. 17, 2011.
(60) Provisional application No. 61/547,813, filed on Oct. 17, 2011.
(60) Provisional application No. 61/547,814, filed on Oct. 17, 2011.

(51) Int. Cl. C23C 16/448; C23C 16/455; C23C 16/46; G05B 15/02; G05D 7/06

(52) U.S. Cl. CPC C23C 16/4486; G05B 15/02; G05D 7/0635; C23C 16/46; C23C 16/455

(57) ABSTRACT

The disclosed embodiments include an integrated multi-headed atomizer and vaporization system and method. The disclosed embodiments provide an innovative approach for generating vapors. As an example, the disclosed embodiments include an apparatus operable to receive one or more liquids in combination with one or more gases simultaneously to generating a vapor of a desired ratio between the liquids and the gases. Additionally, the disclosed embodiments include a system that includes a single set of electronics operable to control all aspects of a vaporization system. Other embodiments, advantages, and novel features are set forth in the detailed description.

### CROSS-REFERENCE TO RELATED APPLICATION

This application claims priority to the following U.S. Provisional Patent Applications: Ser. No. 61/547,814, filed Oct. 17, 2011 entitled INTEGRATED MULTI-HEADED-VAPORIZATION; Ser. No. 61/547,811, filed Oct. 17, 2011 entitled INTEGRATED DIRECT-LIQUID-INJECTION VAPORIZER; and Ser. No. 61/547,813, filed on Oct. 17, 2011 entitled INTEGRATED MANIFOLDED FLOW-RATIO-CONTROLLER, the entire teachings of which are incorporated herein.

### TECHNICAL FIELD OF THE INVENTION

This invention relates generally to atomizer and vapor delivery systems. More particularly, embodiments of the present invention relate to an integrated multi-headed atomizer and vaporization system and method.

### BACKGROUND OF THE INVENTION

There are many applications for which delivery of vapor of different types of liquids is desired. In semiconductor processing, for example, it may be desired to deliver photochemicals, such as photoresist chemicals, in vapor form to a process chamber to control the amount and rate at which these photochemicals are applied as a coating to a semiconductor wafer. In applications of industrial coatings, for another example, it has become relatively common to vaporize liquid Methyl-TriChloro-Silane (SiCl3(CH3)) and react that over a workpiece-surface so as to create a very-hard Silicon-Carbide coating (SiC, venting the residual 3 HCl molecules). To these ends, many types of systems have been designed and utilized to deliver a single vaporized liquid at precisely controlled flow rates and pressures for use in a variety of applications. However, there are many emerging applications where a ‘mixture’ of vaporized liquids must be produced at the same source location, where the constituents' vapor ratios must be precisely controlled due to the variation of stoichiometry of the resultant coating, such as in the creation of Silicon-Oxide Glass ‘doped’ with Boron and/or Phosporous (BPSG).

### SUMMARY OF THE INVENTION

The disclosed embodiments include an apparatus for generating vapors. In one embodiment, the apparatus includes a gas inlet port configured to enable receiving of a gas, a first liquid inlet port configured to enable receiving of a first liquid, and a second liquid inlet port configured to enable receiving of a second liquid. The apparatus also includes a first liquid path configured to enable the flow of the first liquid from the first inlet port to an atomizing chamber and a second liquid path configured to enable the flow of the second liquid from the second inlet port to the atomizing chamber. The apparatus has a first orifice configured to enable the gas to pass from the gas inlet port to the atomizing chamber to atomize the first liquid and the second liquid with the gas to produce an atomized aerosol. The apparatus includes a heat exchanger for vaporing the atomized aerosol into a vapor.

Another disclosed embodiment includes a system for generating vapors. The system utilizes an embodiment of the apparatus as described in the preceding paragraph. In one embodiment, the system also includes a single device configured to provide the gas, the first liquid, and the second liquid to the apparatus. In alternative embodiments, the system may include multiple devices (e.g., flow controllers) that are configured to provide the one or gases and liquids to the vaporizing apparatus. The system further includes a single set of electronics that is configured to control either the single device or the multiple devices to produce desired flow rates of one or more gases and one or more liquids. In certain embodiments, the single set of electronics controller also monitors and controls all operations of the vaporizer.

Additional embodiments, advantages, and novel features are set forth in the detailed description.

### BRIEF DESCRIPTION OF THE DRAWINGS

Illustrative embodiments of the present invention are described in detail below with reference to the attached drawing figures, which are incorporated by reference herein and wherein:

FIG. 1 is a diagram illustrating an example of an existing vaporizer;

FIG. 2 is a diagram illustrating a vaporizer in accordance with one embodiment;

FIG. 3 is a diagram illustrating a vaporizer in accordance with a second embodiment;

FIG. 4 is a diagram illustrating a vaporizer in accordance with a third embodiment;

FIG. 5 is a diagram illustrating a vaporizer in accordance with a fourth embodiment;

FIG. 6 is a diagram illustrating a front face perspective of a multi-headed vaporizer in accordance with the disclosed embodiments; and

FIG. 7 is a block diagram illustrating a common set of electronics controller in accordance with the disclosed embodiments.

### DETAILED DESCRIPTION OF THE DRAWINGS

The invention and the various features and advantageous details thereof are explained more fully with reference to the nonlimiting embodiments that are illustrated in the accompanying drawings and detailed in the following description. Descriptions of well-known starting materials, processing techniques, components, and equipment are omitted so as not to unnecessarily obscure the invention in detail. It should be understood, however, that the detailed description and the specific examples, while indicating particular embodiments of the invention, are given by way of illustration only and not by way of limitation. Various substitutions, modifications, additions, and/or rearrangements within the spirit and/or scope of the underlying inventive concept will become apparent to those skilled in the art from this disclosure.

Other features and advantages of the disclosed embodiments will be or will become apparent to one of ordinary skill in the art upon examination of the following figures and detailed description. It is intended that all such additional features and advantages be included within the scope of the disclosed embodiments. Further, the illustrated figures are only exemplary and are not intended to assert or imply any limitation with regard to the environment, architecture, design, or process in which different embodiments may be implemented.

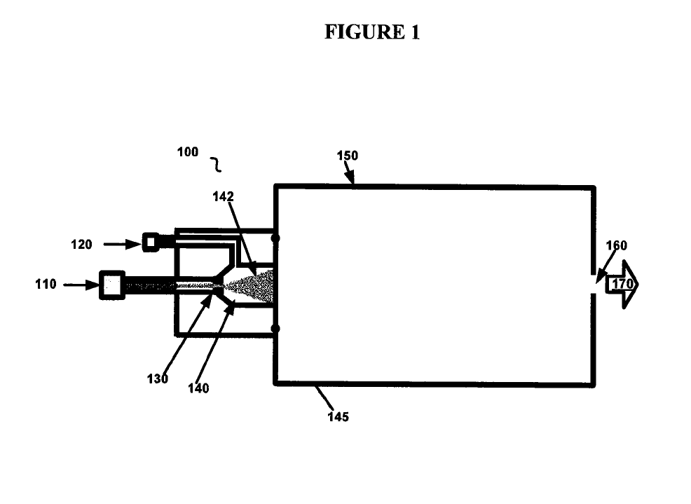

Beginning with FIG. 1, a diagram illustrating an example of an existing vaporizer 100 is disclosed. The vaporizer 100 includes a gas inlet port 110 and a liquid inlet port 120 for respectively receiving a gas and a liquid. A gas, as referenced herein, is an air-like substance which expands freely to fill any space available, irrespective of its quantity. Examples of gases that may be employed in accordance with the disclosed embodiments include, but not limited to, nitrogen, oxygen, argon, and helium. A liquid, as referenced herein, is an aqueous-like substance having definite volume but no fixed shape. Examples of liquids that may be employed in accordance with the disclosed embodiments include, but not limited to, water and various chemical compounds. For instance, in certain embodiments chemicals that decompose into silicate, chemicals that decompose into phosphate, and/or chemicals that decompose into borate may be employed as the liquid agent.

In the disclosed embodiment, the gas entering the gas inlet port 110 passes through an orifice 130 and into an atomizing chamber 140, where it is combined with the liquid from the liquid inlet port 120 for atomizing the liquid to form a droplet aerosol 142 for vaporization. A purpose of the orifice 130 is to increase the velocity of the gas entering through port 110. The increased velocity provides the energy to shear the liquid entering through the liquid inlet port 120 into fine droplets for evaporation. For instance, a small orifice may be utilized for low gas flows, while a larger orifice may be needed to pass higher gas flow rates at high velocities.

The atomizing chamber 140 is coupled and sealed to the heat exchanger 150 via seals 145. The droplet aerosol 142 produced in the atomizing chamber 140 is pushed through the heat exchanger 150 and is vaporized to form a gas/vapor mixture. The heat exchanger 150 is precisely sized to provide the enthalpy-of-vaporization of the liquid and the energy required to elevate the temperature of the resultant vapor/gas mixture to the end-user's reaction-chamber requirements for coating applications. The resulting gas/vapor mixture then flows out of the heat exchanger 150 through an outlet 160 to a customer process 170 (e.g., for thin film deposition and/or semiconductor device fabrication).

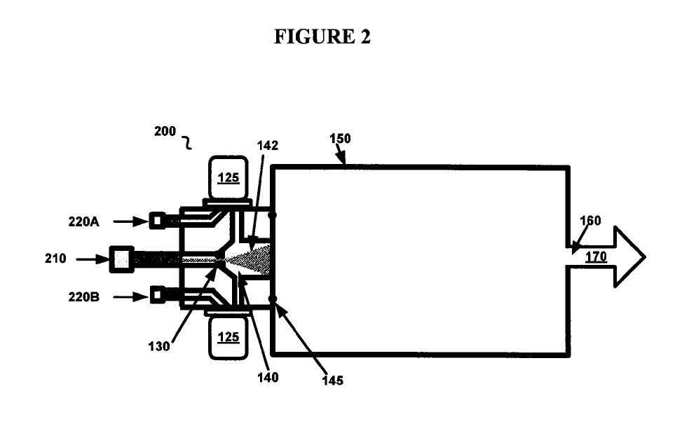

FIGS. 2 through 5 (and their prose descriptions below) provide information on a variety of physical configurations of atomizers into a common heat-exchanger, for the purpose of vaporizing multiple liquids, at either fixed or variable flow ratios (e.g. stoichiometries). Choice of one of these physical configurations will be made given application specifics. These issues include: a) relative flowrate ranges of the multiple liquid constituents, b) potential for reactivity between the liquid constituents, and c) potential for reactivity of the multiple carrier-gas(es) and liquids.

To begin with, FIG. 2 depicts a multi-headed vaporizer 200 in accordance with one embodiment. In the depicted embodiment, the multi-headed vaporizer 200 includes two liquid inlet ports, liquid inlet port 220a and liquid inlet port 220b, and a single gas inlet port 210 and a single orifice 230. The liquid inlet port 220a and liquid inlet port 220b enable the multi-headed vaporizer 200 to simultaneously receive two liquids for vaporization with a single common gas. For instance, the multi-headed vaporizer 200 may include a single set of electronics for controlling the precise ratio of a first liquid received through the liquid inlet port 220a to the gas and the ratio of a second liquid received through the liquid inlet port 220b to the gas in order to generate a vapor containing a desired ratio of the two liquids. Alternatively, the single set of electronics may be configured to control the ratio of the first liquid to the second liquid. For example, the ratio of the two liquids (whose flowrates are externally controlled via flow sensors, regulatory valve, and electronics) may be varied anywhere from 100% of the first with 0% of the second, to 0% of the first with 100% of the second. The multi-headed vaporizer 200 can accept multiple liquids that are chemically compatible (will not react) while still in the liquid phase (i.e. prior to vaporization).

In one embodiment, the gas and the two liquids feeding into the multi-headed vaporizer 200 may be from three separate devices (e.g., each of the liquids and the gas may be controlled by separate flow controllers) for controlling the rate of liquid or gas that is received by the multi-headed vaporizer 200. In an alternative embodiment, the gas and the two liquids feeding into the multi-headed vaporizer 200 may be from a single device having a single set of electronics for controlling the rate and the ratio of the liquids and the gas that are fed to the multi-headed vaporizer 200. In another embodiment, a single set of electronics, either embodied in the multi-headed vaporizer 200 or communicatively coupled to the multi-headed vaporizer 200, may be utilized to control all aspects of the multi-headed vaporizer 200 including controlling either the single device or multiple devices feeding the gas and liquids to the multi-headed vaporizer 200. An advantage of this embodiment includes enabling the manufacturer to configure the single set of electronics to monitor and precisely control all aspects of the multi-headed vaporizer 200 including ensuring the proper ratios between the gas and the liquids, the ability to restrict a feed coming into the multi-headed vaporizer 200, and the ability to modify the multi-headed vaporizer 200 including adjusting the liquid valves 125 if necessary.

In addition, in some embodiments, the multi-headed vaporizer 200 may include one or more physically small-internal-volume shutoff valves on the liquid line (liquid valves 125) for restricting one or more of the liquid flows. The liquid valves 125 may be any type of valve including, but not limited to, a rocker valve. The liquid valves 125 may be utilized for various reasons including, but not limited to, creating a partial restriction of a liquid flow to ensuring a complete stoppage of liquid flow through a particular line. For instance, at times there could be suspect reactivity between a gas and a liquid, the liquid valves 125 may be utilized to shut off the liquid to eliminate any residual amount.

In one embodiment, the liquid valves 125 are positioned in very close proximity to the atomizer inlets and thus the orifice. Reasons for positioning the liquid valves 125 in close proximity to the atomizer inlets and the orifice includes the fact that flowrates can be quite small, that transit times in even the narrow diameter tubes can be slow, and due to the desire that long tubing runs not be slowly evacuated by the (typical subatomospheric) low pressure in the heat-exchanger and coatings-reactor, thus creating slow rise and fall times in net vapor delivery rates. For example, in applications where the inventory volume of liquid between the liquid valves 125 and the atomizer is important, these valves may be closely coupled to the atomizer to reduce the volume of liquid between the valve and the atomizer One example of a situation where low inventory volume is important is in a semiconductor manufacturing process involving borophosphosilicate glass (BPSG). The process for creating BPSG uses three liquids where two of the liquids are dopants and are a very small fraction of the total liquid flow. All three chemistries must be present in a critical, predetermined ratio at the outlet of the vaporizer. When a vaporizer is running in a vacuum process, the inventory volume of liquid between the liquid valves 125 and the atomizer can boil off when the liquid flow is shut off, such as between wafers. When the liquid flow is resumed, the high flow liquid will quickly fill the inventory volume, be atomized, and the vapor will quickly appear at the vaporizer outlet. However, for the low flow liquids, little or no liquid will enter the atomizer until the inventory volume is replenished, resulting in no vapor at the outlet of the vaporizer, and an improper mixture of chemistries at the outlet of the vaporizer for a period of time. At very low flow rates, full concentration of the vapor from the low flow liquid may not appear at the outlet of the vaporizer for several minutes. Thus, by keeping the liquid valves 125 closely coupled to the atomizer, the time to needed to replenish the inventory volume is reduced, thus decreasing the time to achieve full concentration of the vapor from the low flow liquid at the outlet.

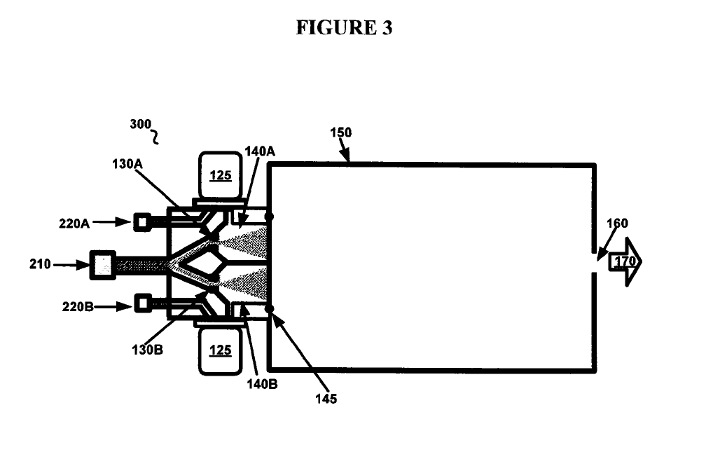

FIG. 3 is a diagram illustrating a multi-headed vaporizer 300 in accordance with a second embodiment. Similar to the multi-headed vaporizer 200, the multi-headed vaporizer 300 includes the two liquid inlet ports, liquid inlet port 220a and liquid inlet port 220b, the single gas inlet port 210, and the liquid valves 125. However, in this embodiment, the multi-headed vaporizer 300 includes dual orifices, a first orifice 130a and a second orifice 130b. In one embodiment, the first orifice 130a is a different size orifice from that of the second orifice 130b. For example, the first orifice 130a may be small to enable precise release of gas at a slow rate for pushing a first liquid received from the liquid inlet port 220a, while the second orifice 130b may be large to enable the precise release of gas at higher flow rate for atomizing a second liquid received from the liquid inlet port 220b. In addition, the atomizing chamber 140 may be separated into a first atomizing chamber 140a for atomizing the first liquid, and a second atomizing chamber 140b for atomizing the second liquid. In certain embodiments, the size/volume of the first atomizing chamber 140a is different in size/volume from that of the second atomizing chamber 140b. Alternatively, in certain embodiments, the volume of the atomizing chambers may be the equal.

In the depicted embodiment of FIG. 3, unlike in FIG. 2, the constituent liquids never mix prior to their change to the vapor phase. Also, in contrast to FIG. 2, the use of separate orifice sizes enables the flowrate of liquid 1 to be ‘orders of magnitude’ larger or smaller than the flowrate of liquid 2. Thus, this embodiment is more capable of providing a small-quantity of ‘dopant’ to a ‘main’ higher-flowrate liquid stream.

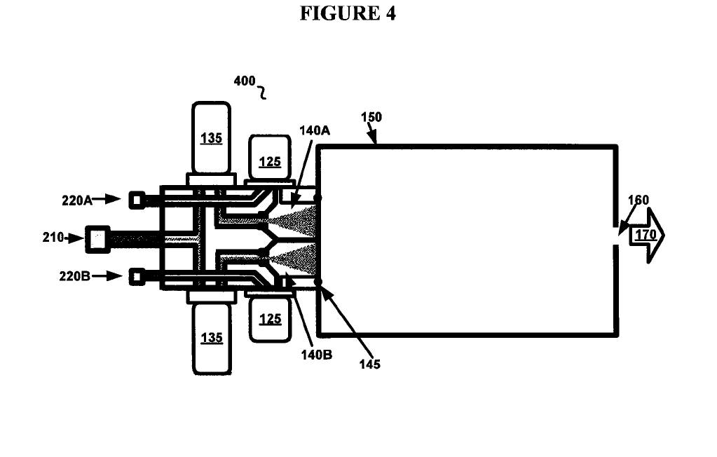

FIG. 4 is a diagram illustrating a multi-headed vaporizer 400 in accordance with another embodiment. Similar to the multi-headed vaporizer 300, the multi-headed vaporizer 400 includes the two liquid inlet ports (220a, 220b), the single gas inlet port 210, the liquid valves 125, the dual orifices (130a, 130b), and the dual atomizing chambers (140a, 140b). However, in this embodiment, the multi-headed vaporizer 400 includes dual gas valves 135.

Similar to the liquid valves 125, the dual gas valves 135 may be utilized to restrict the flow of gas to one or more of the liquids. Localized shutdown of the carrier gas utilizing the gas valves 135 may be desirable when the associated liquid line is flowing at a 0% rate (e.g., to reduce the atomizer plus heat-exchanger net-internal-volume and thus its ‘exhaust’ time).

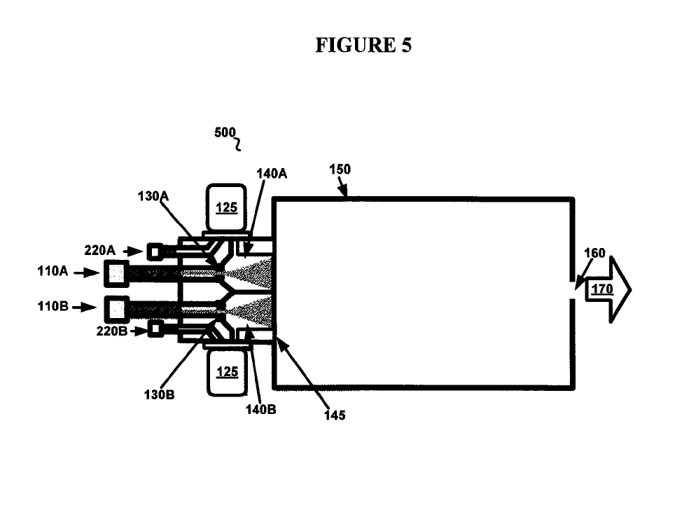

FIG. 5 is a diagram illustrating a multi-headed vaporizer 500 in accordance with yet another embodiment. Similar to the multi-headed vaporizer 300, the multi-headed vaporizer 500 includes the two liquid inlet ports (220a, 220b), the liquid valves 125, the dual orifices (130a, 130b), and the dual atomizing chambers (140a, 140b). However, in this embodiment, the multi-headed vaporizer 500 includes dual gas inlet ports 110a and 110b for enabling the multi-headed vaporizer 500 to create a vapor consisting of a desired ratio between a first gas with a first liquid and a second gas with a second liquid. The respective orifice (130a, 130b) of the multi-headed vaporizer 500 for the first gas may be of the same size or differing size than that of the orifice for the second gas. Additionally, this embodiment (unlike FIGS. 2 through 4) allows for different choices of carrier-gases (e.g. for chemical compatibility). Although not depicted, the addition of a localized gas-shutoff valve (e.g., gas valves 135 as illustrated in FIG. 4) may also be desirable as an extension to the multi-headed vaporizer 500.

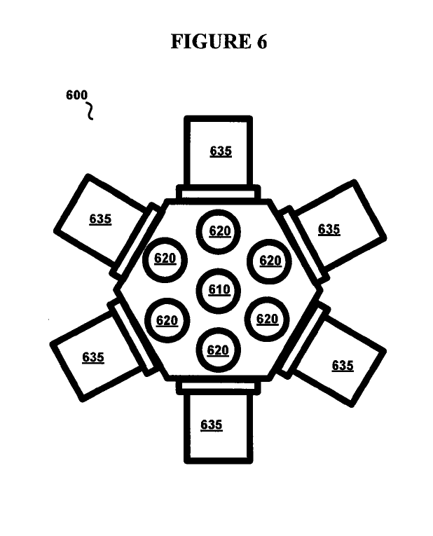

FIG. 6 is a diagram illustrating a front face perspective of a multi-headed vaporizer 600 in accordance with the disclosed embodiments. In the depicted embodiment, the face of the multi-headed vaporizer 600 enables the reception of a single gas in gas inlet port 610 and up to six different liquids via liquid inlet ports 620. This embodiment also includes six liquid isolation valves 635 for enabling the restriction of one or more of the liquids. Other embodiments within the scope of this disclosure may include any number of gas inlet ports and/or liquid inlet ports.

Additionally, the inventors of the above disclosed embodiments recognize certain benefits and limitations associated with the use of current vaporizers. For example, the flow of carrier gas across a fixed orifice size, with a known pressure-drop, can create a sonic condition that creates forces that we use to ‘shear’ an impinging liquid into micro-droplets. The resultant high surface-area of the micro-droplets, in the presence of sufficient thermal energy within the heat-exchanger, optimizes the opportunity for phase-change from liquid to vapor. In addition, the simple presence of carrier-gas alongside the vapor will ‘dilute’ the liquid-turned-vapor, such that only the partial-pressure of the vapor needs to be ‘below’ the equilibrium-vapor-pressure-curve for certain molecular-species. However, below a given gas-flowrate for this fixed orifice size, this required sonic/force/shear effect drops out, thus removing its utility in vaporization. Additionally, above a given gas-flowrate for this fixed orifice size, the maximum flowrate of gas is ‘choked’, thus limiting its ability to impart force as well as limiting its dilution potential for partial-pressure effects.

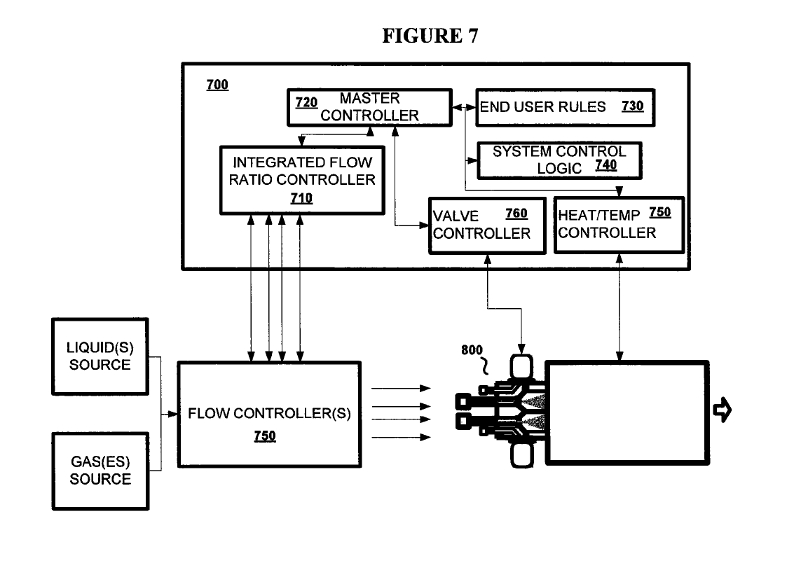

Accordingly, the inventors recognize that the coordination of actual gas and liquid flowrates (from their minimum to maximum volumes) with the disclosed embodiments would be advantageous. Thus, in reference to FIG. 7, the disclosed embodiments include a common controller/set of electronics 700 that is configured to control a set of flow control devices or a single flow control device 750 to regulate both gas and liquid flow into a vaporizer embodiment 800. Embodiments of vaporizer 800 include, but are not limited to, the disclosed vaporizer embodiments of FIGS. 1-5. The regulation of both gas and liquid flows by a single common set of electronics, such as the common set of electronics controller 700, as opposed to separate electronics for gas vs. liquid controllers, eases the burden on the end-user, who formerly was required to write custom-code to calculate these flow ratios.

In addition, the common set of electronics controller 700 is configured to regulate the multiple flowrates of both liquid and gas not only from a steady-state perspective, but also from a sequencing perspective (e.g. startup and shutdown). In one embodiment, the common set of electronics controller 700, using an integrated flow ratio controller 710, is configured to establish carrier-gas-flow before liquid is flowing, and after liquid has ceased flowing, which former means of regulating flowrates in separate controllers (one for gas1, another one for liquid1, etc.) is incapable of performing. In certain embodiments, the integrated flow ratio controller 710 may communicate with a master controller 720 to implement a proportional-integral-derivative (PID) control loop for monitoring and controlling the multiple flowrates of both liquid and gas from the flow controllers 750 that are passed to the vaporizer 800. For example, the PID control loop may continually monitor and adjust a proportional valve of a flow controller to maintain a desired setpoint. The master controller 720 may be implemented using one or more processors that are configured to execute instructions stored in memory, such as, but not limited to, system control logic 740, for managing all aspects of the a vaporizer system.

The disclosed coordination of multiple flows (i.e. ‘ratio-of ratios’) utilizing the common set of electronics controller 700 is easier on the end-user, as it only requires for an end user to populate a few tabular entries, as opposed to requiring the end user to write custom code. For instance, in accordance with the disclosed embodiments, use of the common set of electronics controller 700 simplifies the process for enabling the end-user to define the ‘tabular rules’ as stored in an end user rules table/database 730, such as, but not limited to, establishing minimum and maximum flow. Additionally, the end user may define the desired total flow and ratio of each of the gases and liquids for each of the flow controller devices. As an example, the user may define for a given/desired total flow rate that the ratios of four gas components be 1.0 to 0.75 to 0.5 to 1.75. The user may further define such rules requiring the first gas to flow at a desired ratio, but can never exceed a flow >2 liters per minute (lpm); that the second gas flow at a desired ratio, but can never be allowed to flow <0.5 lpm; that a third gas flow at a desired ratio, except if calculated to be <0.25 lpm, then the third gas would be cutoff to 0; and the fourth gas will be the ‘make-up’ line; as the rules above engage to constrain contribution, the fourth gas will make up the remaining total flow. Utilizing the common set of electronics controller 700, a single controller is able to adjust and manipulate each of the flow controller devices during operation to ensure the desired total flow, ratio, and constraints of the multiple gases and liquids flows entering the vaporizer 800 in accordance with the user-specified rules.

Further, in certain embodiments, the common set of electronics controller 700 may also implement diagnostic checks (e.g., comparison of desired flowrates to actual flowrates) and provide an alert/alarm in response to a failure of a diagnostic check. The common set of electronics controller 700 may also manipulate during operation one or more valves on the vaporizer 800 to reduce or restrict one or more of the multiple gas and liquid flows.

In addition to controlling the flow rates and ratios of gases and liquids into a vaporizer, in some embodiments, the common set of electronics controller 700 is further configured to control the heat-delivered to the heat-exchanger of the vaporizer 800 and its temperature feedback utilizing a heat/temperature controller 750. In many cases, the liquids being vaporized are quite ‘delicate’, in that excessive temperatures can cause molecular degradation (e.g., scalding, particulate debris, fouling of flow paths, etc.). Thus, the common set of electronics controller 700 is specially configured to supply a precise amount of energy to cause the phase-change, plus the temperature output at customer-desired reaction condition, but not produce excessive temperatures that can cause molecular degradation.

Accordingly, the disclosed embodiments provide various embodiments of a multi-headed vaporizer and a vaporizing system that includes a common set of electronics controller that precisely controls all aspects of the vaporizing system. As previously stated, the above description including the diagrams are intended merely as examples of the disclosed embodiments and is not intended to limit the structure, process, or implementation of the disclosed embodiments. As understood by one of ordinary skill in this art that certain aspects of the disclosed embodiments described herein may be implemented as firmware, firmware/software combination, firmware/hardware combination, or a hardware/firmware/software combination.

It is further understood that various modifications may be made therein and that the subject matter disclosed herein may be implemented in various forms and examples, and that the teachings may be applied in numerous applications, only some of which have been described herein. For instance, while the multi-headed vaporizer 500 is illustrated as having only two liquid inlet ports and two gas inlet ports, the disclosed embodiments may be implemented with any number of liquid and/or gas inlet ports for receiving various combinations of liquids and gases. In addition, in certain embodiments, the disclosed embodiments may include a vaporizer that includes more gas inlet ports than liquid inlet ports. For example, the disclosed embodiments may include a vaporizer that is configured to have a single liquid inlet that feeds into dual atomizer chambers that are atomized by two different gases received via dual gas inlet ports. Additionally, in some embodiments, the common set of electronics controller 700 may also include one or more pressure sensing device for monitoring and controlling the pressure of the multiple gas and liquid flows. It is intended by the following claims to claim any and all applications, modifications, and variations that fall within the true scope of the present teachings.

1. An apparatus for generating vapors, the apparatus comprising:
a gas inlet port configured to enable receiving of a first gas;
a gas path between the gas inlet port and an atomizing chamber;
a first liquid inlet port configured to enable receiving of a first liquid;
a first liquid path configured to enable flow of the first liquid from the first inlet port to the atomizing chamber;
a second liquid inlet port configured to enable receiving of a second liquid;
a second liquid path configured to enable the flow of the second liquid from the second inlet port to the atomizing chamber;
an interface located between the gas path and the atomizing chamber, wherein the interface is configured to create a force for shearing the first liquid and the second liquid into micro-droplets; and
a heat exchanger configured to produce a gas/vapor mixture from the first liquid, the second liquid, and the first gas.

2. The apparatus of claim 1, further comprising at least one liquid isolation valve operable to restrict a flow of at least one of the first liquid in the first liquid path and the second liquid in the second liquid path.

3. The apparatus of claim 1, wherein the interface is a first orifice having a fixed size with a known pressure drop.

4. The apparatus of claim 3, wherein the atomizing chamber comprises of a first atomizing chamber and a second atomizing chamber, and further comprising:
a second orifice configured to enable the first gas to pass from the gas inlet port to the second atomizing chamber, and wherein the first orifice is configured to enable the first gas to pass from the gas inlet port to the first atomizing chamber.

5. The apparatus of claim 4, wherein the first orifice is a different size than the second orifice.

6. The apparatus of claim 4, wherein the first atomizing chamber is a different size than the second atomizing chamber.

7. The apparatus of claim 4, further comprising at least one gas isolation valve operable to restrict a flow of the gas to at least one of the first atomizing chamber and the second atomizing chamber.

8. The apparatus of claim 3, wherein the first orifice is sized to generate a force that shears the first liquid and the second liquid into micro-droplets that maximizes a surface area covered by the micro-droplets.

9. The apparatus of claim 1, further comprising:
an additional number of liquid inlet ports for receiving n additional number of liquids, wherein n is a positive number.

10. The apparatus of claim 9, further comprising:
n+2 number of liquid isolation valves, each operable to restrict a flow of a liquid.

11. The apparatus of claim 1, further comprising:
a single set of electronics operable to control a ratio of the first liquid to the first gas and the ratio of the second liquid to the first gas.

12. A system for generating vapors, the system comprising:
an apparatus, the apparatus comprising:
a gas inlet port configured to enable receiving of a first gas;
a first liquid inlet port configured to enable receiving of a first liquid;
a first liquid path configured to enable the flow of the first liquid from the first inlet port to an atomizing chamber;
a second liquid inlet port configured to enable receiving of a second liquid;
a second liquid path configured to enable the flow of the second liquid from the second inlet port to the atomizing chamber; and
a heat exchanger configured to produce a gas/vapor mixture from the first liquid, the second liquid, and the first gas;
a single device configured to provide the first gas, the first liquid, and the second liquid to the apparatus; and
a single set of electronics configured to control the single device to produce a desired gas flow rate of the first gas, a desired first liquid flow rate of the first liquid, and a desired second liquid flow rate of the second liquid.

13. The system of claim 12, wherein the single set of electronics is further configured to control operations of the apparatus to provide a desired ratio between the first liquid and the first gas, and a second desired ratio between the second liquid and the first gas.

14. An apparatus for generating vapors, the apparatus comprising:
a first gas inlet port configured to enable receiving of a first gas;
a second gas inlet port configured to enable receiving of a second gas;
a first liquid inlet port configured to enable receiving of a first liquid;
a first liquid path configured to enable the flow of the first liquid from the first inlet port to a first atomizing chamber and to a second atomizing chamber;
a first orifice configured to enable the first gas to pass from the first gas inlet port to the first atomizing chamber for producing a first atomized aerosol using the first gas and first liquid;
a second orifice configured to enable the second gas to pass from the second gas inlet port to the second atomizing chamber for producing a second atomized aerosol using the second gas and second liquid; and
a heat exchanger for vaporing the first atomized aerosol and the second atomized aerosol into a vapor.

15. A common set of electronics controller, comprising:
memory for storing control instructions and end user operational parameters; and
one or more processors configured to execute instructions, wherein the one or more processors execute the control instructions using the end user operational parameters to:
regulate a total flow of at least one gas flow and at least one liquid flow of external flow controllers to a vaporizer; and
control operations of the vaporizer.

16. The common set of electronics controller of claim 15, wherein the one or more processors further execute the control instructions using the end user operational parameters to regulate the total flow of at least one gas flow and at least two liquid flows of external flow controllers to the vaporizer.

17. The common set of electronics controller of claim 15, wherein the one or more processors further execute the control instructions using the end user operational parameters to regulate the total flow of at least two gas flows and at least two liquid flows of external flow controllers to the vaporizer.

18. The common set of electronics controller of claim 15, wherein the one or more processors further execute the control instructions using the end user operational parameters to regulate the a ratio between the at least one gas flow and at least two liquid flows of the external flow controllers to the total flow.

19. The common set of electronics controller of claim 15, wherein the one or more processors further execute the control instructions using the end user operational parameters to regulate a heat temperature of the vaporizer.

20. The common set of electronics controller of claim 15, wherein controlling operations of the vaporizer include controlling an integrated gas flow shutoff valve.
